(19) United States
(12) Patent Application Publication
(10) Pub. No.: US 2017/0212913 A1
(43) Pub. Date: Jul. 27, 2017

(54) MRI DATABASE AND MECHANISM FOR SEARCHING

(71) Applicant: Boston Scientific Neuromodulation Corporation, Valencia, CA (US)

(72) Inventor: Manish Umesh Kurse, Northridge, CA (US)

(21) Appl. No.: 15/408,036

(22) Filed: Jan. 17, 2017

Related U.S. Application Data
(60) Provisional application No. 62/281,957, filed on Jan. 22, 2016.

(51) Int. Cl. G06F 17/30; G01R 33/28

(52) U.S. Cl. CPC G06F 17/30268; G06F 17/30991; G01R 33/288

(57) ABSTRACT

An example of a system may include a processor subsystem; and a memory device comprising instructions, which when executed by the processor subsystem, cause the processor subsystem to: access at an application executing on a user device, a set of device characteristics of an implantable medical device (IMD); search a database of magnetic resonance imaging (MRI) scanners to identify a search result, the search result including MRI scanners that are safe for the IMD based on the set of device characteristics, and the search result in a geographic area; and present the search result on the user device.

### CLAIM OF PRIORITY

This application claims the benefit of priority under 35 U.S.C. §119(e) of U.S. Provisional Patent Application Ser. No. 62/281,957, filed on Jan. 22, 2016, which is herein incorporated by reference in its entirety.

### TECHNICAL FIELD

This document relates generally to medical devices, and more particularly, to systems, devices, and methods for identifying and locating appropriate testing facilities.

### BACKGROUND

Neuromodulation, which includes neurostimulation, has been proposed as a therapy for a number of conditions. Examples of neurostimulation include Spinal Cord Stimulation (SCS), Deep Brain Stimulation (DBS), Peripheral Nerve Stimulation (PNS), and Functional Electrical Stimulation (FES). Implantable neurostimulation systems have been applied to deliver such a therapy. An implantable neurostimulation system may include an implantable neurostimulator, also referred to as an implantable pulse generator (IPG), and one or more implantable leads each including one or more electrodes. The implantable neurostimulator delivers neurostimulation energy through one or more electrodes placed on or near a target site in the nervous system. An external programming device is used to program the implantable neurostimulator with stimulation parameters controlling the delivery of the neurostimulation energy.

The neurostimulation energy may be delivered in the form of electrical neurostimulation pulses. The delivery is controlled using stimulation parameters that specify spatial (where to stimulate), temporal (when to stimulate), and informational (patterns of pulses directing the nervous system to respond as desired) aspects of a pattern of neurostimulation pulses. Many current neurostimulation systems are programmed to deliver periodic pulses with one or a few uniform waveforms continuously or in bursts. However, neural signals may include more sophisticated patterns to communicate various types of information, including sensations of pain, pressure, temperature, etc.

Recent research has shown that the efficacy and efficiency of certain neurostimulation therapies can be improved, and their side-effects can be reduced, by using patterns of neurostimulation pulses that emulate natural patterns of neural signals observed in the human body.

### SUMMARY

Example 1 includes subject matter (such as a device, apparatus, or machine) comprising: a processor subsystem; and a memory device comprising instructions, which when executed by the processor subsystem, cause the processor subsystem to: access at an application executing on a user device, a set of device characteristics of an implantable medical device (IMD); search a database of magnetic resonance imaging (MRI) scanners to identify a search result, the search result including MRI scanners that are safe for the IMD based on the set of device characteristics, and the search result in a geographic area; and present the search result on the user device.

In Example 2, the subject matter of Example 1 may include, wherein the set of device characteristics includes an MRI safety limitation of the IMD.

In Example 3, the subject matter of any one of Examples 1 to 2 may include, wherein the MRI safety limitation includes at least one of: a static magnetic field rating, a spatial gradient field rating, a maximum whole-body-averaged specific absorption rate (SAR) during normal operating mode, an upper value of a root mean square of a magnetic field, or a body scan location limitation.

In Example 4, the subject matter of any one of Examples 1 to 3 may include, wherein the instructions to access the set of device characteristics comprise instructions to: query the IMD, and receive the set of device characteristics from the IMD.

In Example 5, the subject matter of any one of Examples 1 to 4 may include, wherein the instructions to access the set of device characteristics comprise instructions to: query a patient database; and receive the set of device characteristics from the patient database.

In Example 6, the subject matter of any one of Examples 1 to 5 may include, wherein the instructions to search the database of MRI scanners to identify the search result comprise instructions to: receive a geographic search constraint at the user device; and search the database of URI scanners in the geographic area constrained by the geographic search constraint.

In Example 7, the subject matter of any one of Examples 1 to 6 may include, wherein the geographic search constraint includes a central locus and a search distance threshold.

In Example 8, the subject matter of any one of Examples 1 to 7 may include, wherein the central locus corresponds to a geolocation of the user device.

In Example 9, the subject matter of any one of Examples 1 to 8 may include, wherein the instructions to present the search result on the user device comprise instructions to: present aspects of the MRI scanners in the search result.

In Example 10, the subject matter of any one of Examples 1 to 9 may include, instructions to: obtain directions for use for the IMD for a specific MRI scanner of the MRI scanners in the search result; and present the directions for use on the user device.

In Example 11, the subject matter of any one of Examples 1 to 10 may include, instructions to: access a body scan location limitation from the set of device characteristics; and present a graphical representation of a body with indications corresponding the body scan location limitation.

In Example 12, the subject matter of any one of Examples 1 to 11 may include, instructions to: present the search result on a first user interface screen; and present a device labeling on a second user interface screen.

in Example 13, the subject matter of any one of Examples 1 to 12 may include, wherein the user device comprises a smartphone.

Example 14 includes a machine-readable medium including instructions, which when executed by a machine, cause the machine to perform operations of any of the claims 1-13.

Example 15 includes a method to perform operations of any of the claims 1-13.

Example 16 includes subject matter (such as a device, apparatus, or machine) comprising: a processor subsystem; and a memory device comprising instructions, which when executed by the processor subsystem, cause the processor subsystem to: access at an application executing on a user device, a set of device characteristics of an implantable medical device (IMD); search a database of magnetic resonance imaging (MRI) scanners to identify a search result, the search result including MRI scanners that are safe for the IMD based on the set of device characteristics, and the search result in a geographic area; and present the search result on the user device.

In Example 17, the subject matter of Example 16 may include, wherein the set of device characteristics includes an MRI safety limitation of the IMD.

In Example 18, the subject matter of any one of Examples 16 to 17 may include, wherein the MRI safety limitation includes at least one of: a static magnetic field rating, a spatial gradient field rating, a maximum whole-body-averaged specific absorption rate (SAR) during normal operating mode, an upper value of a root mean square of a magnetic field, or a body scan location limitation.

In Example 19, the subject matter of any one of Examples 16 to 18 may include, wherein the instructions to access the set of device characteristics comprise instructions to: query the IMD; and receive the set of device characteristics from the IMD.

In Example 20, the subject matter of any one of Examples 16 to 19 may include, wherein the instructions to access the set of device characteristics comprise instructions to: query a patient database; and receive the set of device characteristics from the patient database.

In Example 21, the subject matter of any one of Examples 16 to 20 may include, wherein the instructions to search the database of MRI scanners to identify the search result comprise instructions to: receive a geographic search constraint at the user device; and search the database of MRI scanners in the geographic area constrained by the geographic search constraint.

In Example 22, the subject matter of any one of Examples 16 to 21 may include, wherein the geographic search constraint includes a central locus and a search distance threshold.

In Example 23, the subject matter of any one of Examples 16 to 22 may include, wherein the central locus corresponds to a geolocation of the user device.

In Example 24, the subject matter of any one of Examples 16 to 23 may include, wherein the instructions to present the search result on the user device comprise instructions to: present aspects of the MRI scanner in the search result.

In Example 25, the subject matter of any one of Examples 16 to 24 may include, instructions to: obtain directions for use for the IMD for a specific MRI scanner of the MRI scanners in the search result; and present the directions for use on the user device.

In Example 26, the subject matter of any one of Examples 16 to 25 may include, instructions to: access a body scan location limitation from the set of device characteristics; and present a graphical representation of a body with indications corresponding the body scan location limitation.

In Example 27, the subject matter of any one of Examples 16 to 26 may include, instructions to: present the search result on a first user interface screen; and present a device labeling on a second user interface screen.

Example 28 includes subject matter (such as a method, means for performing acts, machine readable medium including instructions that when performed by a machine cause the machine to performs acts, or an apparatus to perform) comprising: accessing at an application executing on a user device, a set of device characteristics of an implantable medical device (IMD); searching a database of magnetic resonance imaging (MRI) scanners to identify a search result, the search result including MRI scanners that are safe for the IMD based on the set of device characteristics, and the search result in a geographic area; and presenting the search result on the user device.

In Example 29, the subject matter of Example 28 may include, wherein the set of device characteristics includes an MRI safety limitation of the IMD.

In Example 30, the subject matter of any one of Examples 28 to 29 may include, wherein the MRI safety limitation includes at least one of: a static magnetic field rating, a spatial gradient field rating, a maximum whole-body-averaged specific absorption rate (SAR) during normal operating mode, an upper value of a root mean square of a magnetic field, or a body scan location limitation.

In Example 31, the subject matter of any one of Examples 28 to 30 may include, wherein accessing the set of device characteristics comprises: querying the IMD; and receiving the set of device characteristics from the IMD.

In Example 32, the subject matter of any one of Examples 28 to 31 may include, wherein accessing the set of device characteristics comprises: querying a patient database; and receiving the set of device characteristics from the patient database.

In Example 33, the subject matter of any one of Examples 28 to 32 may include, wherein searching the database of MRI scanners to identify the search result comprises: receiving a geographic search constraint at the user device; and searching the database of MRI scanners in the geographic area constrained by the geographic search constraint.

In Example 34, the subject matter of any one of Examples 28 to 33 may include, wherein presenting the search result on the user device comprises: presenting aspects of the MRI scanners in the search result.

Example 35 includes subject matter (such as a machine-readable or computer-readable medium) comprising including instructions, which when executed by a machine, cause the machine to: access at an application executing on a user device, a set of device characteristics of an implantable medical device (IMD); search a database of magnetic resonance imaging (MRI) scanners to identify a search result, the search result including MRI scanners that are safe for the IMD based on the set of device characteristics, and the search result in a geographic area; and present the search result on the user device.

This Summary is an overview of some of the teachings of the present application and not intended to be an exclusive or exhaustive treatment of the present subject matter. Further details about the present subject matter are found in the detailed description and appended claims. Other aspects of the disclosure will be apparent to persons skilled in the art upon reading and understanding the following detailed description and viewing the drawings that form a part thereof each of which are not to be taken in a limiting sense. The scope of the present disclosure is defined by the appended claims and their legal equivalents.

### BRIEF DESCRIPTION OF THE DRAWINGS

Various embodiments are illustrated by way of example in the figures of the accompanying drawings. Such embodiments are demonstrative and not intended to be exhaustive or exclusive embodiments of the present subject matter.

FIG. 1 illustrates a portion of a spinal cord.

FIG. 2 illustrates, by way of example, an embodiment of a neuromodulation system.

FIG. 3 illustrates, by way of example, an embodiment of a modulation device, such as may be implemented in the neuromodulation system of FIG. 2.

FIG. 4 illustrates, by way of example, an embodiment of a programming device, such as may be implemented as the programming device in the neuromodulation system of FIG. 2.

FIG. 5 illustrates, by way of example, an implantable neuromodulation system and portions of an environment in which system may be used.

FIG. 6 illustrates, by way of example, an embodiment of an SCS system.

FIG. 7 illustrates, by way of example, an embodiment of an operational environment.

FIG. 8 illustrates, by way of example, an embodiment of a graphical user interface.

FIG. 9 illustrates, by way of example, an embodiment of a graphical user interface.

FIG. 10 illustrates, by way of example, an embodiment of a graphical user interface.

FIG. 11 illustrates, by way of example, an embodiment of data and control flow in a system.

FIG. 12 illustrates, by way of example, an embodiment of a system.

FIG. 13 illustrates, by way of example, an embodiment of a method.

FIG. 14 is a block diagram illustrating a machine in the example form of a computer system, within which a set or sequence of instructions may be executed to cause the machine to perform any one of the methodologies discussed herein, according to an example embodiment.

### DETAILED DESCRIPTION

The following detailed description of the present subject matter refers to the accompanying drawings which show, by way of illustration, specific aspects and embodiments in which the present subject matter may be practiced. These embodiments are described in sufficient detail to enable those skilled in the art to practice the present subject matter. Other embodiments may be utilized and structural, logical, and electrical changes may be made without departing from the scope of the present subject matter. References to “an”, “one”, or “various” embodiments in this disclosure are not necessarily to the same embodiment, and such references contemplate more than one embodiment. The following detailed description is, therefore, not to be taken in a limiting sense, and the scope is defined only by the appended claims, along with the full scope of legal equivalents to which such claims are entitled.

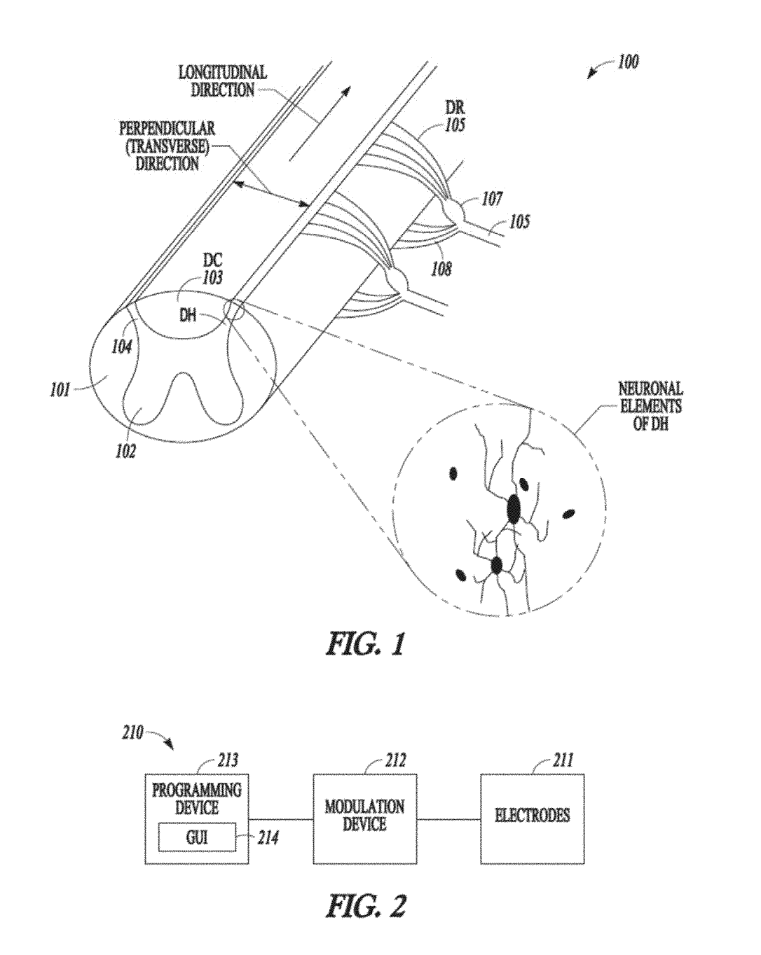

Various embodiments described herein involve spinal cord modulation. A brief description of the physiology of the spinal cord and related apparatus is provided herein to assist the reader. FIG. 1 illustrates, by way of example, a portion of a spinal cord 100 including white matter 101 and gray matter 102 of the spinal cord. The gray matter 102 includes cell bodies, synapse, dendrites, and axon terminals. Thus, synapses are located in the gray matter. White matter 101 includes myelinated axons that connect gray matter areas. A typical transverse section of the spinal cord includes a central “butterfly” shaped central area of gray matter 102 substantially surrounded by an ellipse-shaped outer area of white matter 101. The white matter of the dorsal column (DC) 103 includes mostly large myelinated axons that form afferent fibers that run in an axial direction. The dorsal portions of the “butterfly” shaped central area of gray matter are referred to as dorsal horns (DR) 104. In contrast to the DC fibers that run in an axial direction, DH fibers can be oriented in many directions, including perpendicular to the longitudinal axis of the spinal cord. Examples of spinal nerves 105 are also illustrated, including a dorsal root (DR) 105, dorsal root ganglion 107 and ventral root 108. The dorsal root 105 mostly carries sensory signals into the spinal cord, and the ventral root functions as an efferent motor root. The dorsal and ventral roots join to form mixed spinal nerves 105.

SCS has been used to alleviate pain. A therapeutic goal for conventional SCS programming has been to maximize stimulation (i.e., recruitment) of the DC fibers that run in the white matter along the longitudinal axis of the spinal cord and minimal stimulation of other fibers that run perpendicular to the longitudinal axis of the spinal cord (dorsal root fibers, predominantly), as illustrated in FIG. 1. The white matter of the DC includes mostly large myelinated axons that form afferent fibers. While the full mechanisms of pain relief are not well understood, it is believed that the perception of pain signals is inhibited via the gate control theory of pain, which suggests that enhanced activity of innocuous touch or pressure afferents via electrical stimulation creates interneuronal activity within the DH of the spinal cord that releases inhibitory neurotransmitters (Gamma-Aminobutyric Acid (GABA), glycine), which in turn, reduces the hypersensitivity of wide dynamic range (WDR) sensory neurons to noxious afferent input of pain signals traveling from the dorsal root (DR) neural fibers that innervate the pain region of the patient, as well as treating general WDR ectopy. Consequently, the large sensory afferents of the DC nerve fibers have been targeted for stimulation at an amplitude that provides pain relief. Current implantable neuromodulation systems typically include electrodes implanted adjacent, i.e., resting near, or upon the dura, to the dorsal column of the spinal cord of the patient and along a longitudinal axis of the spinal cord of the patient.

Activation of large sensory DC nerve fibers also typically creates the paresthesia sensation that often accompanies standard SCS therapy. Some embodiments deliver therapy where the delivery of energy is perceptible due to sensations such as paresthesia. Although alternative or artifactual sensations, such as paresthesia, are usually tolerated relative to the sensation of pain, patients sometimes report these sensations to be uncomfortable, and therefore, they can be considered an adverse side-effect to neuromodulation therapy in some cases. Some embodiments deliver sub-perception therapy that is therapeutically effective to treat pain, for example, but the patient does not sense the delivery of the modulation field (e.g. paresthesia), Sub-perception therapy may include higher frequency modulation (e.g. about 1500 Hz or above) of the spinal cord that effectively blocks the transmission of pain signals in the afferent fibers in the DC. Some embodiments herein selectively modulate DH tissue or DR tissue over DC tissue to provide sub-perception therapy. For example, the selective modulation may be delivered at frequencies less than 1,200 Hz. The selective modulation may be delivered at frequencies less than 1,000 Hz in some embodiments. In some embodiments, the selective modulation may be delivered at frequencies less than 500 Hz. In some embodiments, the selective modulation may be delivered at frequencies less than 350 Hz. In some embodiments, the selective modulation may be delivered at frequencies less than 130 Hz. The selective modulation may be delivered at low frequencies (e.g. as low as 2 Hz). The selective modulation may be delivered even without pulses (e.g. 0 Hz) to modulate some neural tissue. By way of example and not limitation, the selective modulation may be delivered within a frequency range selected from the following frequency ranges: 2 Hz to 1,200 Hz; 2 Hz to 1,000 Hz, 2 Hz to 500 Hz; 2 Hz to 350 Hz; or 2 Hz to 130 Hz. Systems may be developed to raise the lower end of any these ranges from 2 Hz to other frequencies such as, by way of example and not limitation, 10 Hz, 20 Hz, 50 Hz or 100 Hz. By way of example and not limitation, it is further noted that the selective modulation may be delivered with a duty cycle, in which stimulation (e.g. a train of pulses) is delivered during a Stimulation ON portion of the duty cycle, and is not delivered during a Stimulation OFF portion of the duty cycle. By way of example and not limitation, the duty cycle may be about 10%±5%, 20%±5%, 30%±5%, 40% ±5%, 50%±5% or 60% ±5%. For example, a burst of pulses for 10 ms during a Stimulation ON portion followed by 15 ms without pulses corresponds to a 40% duty cycle.

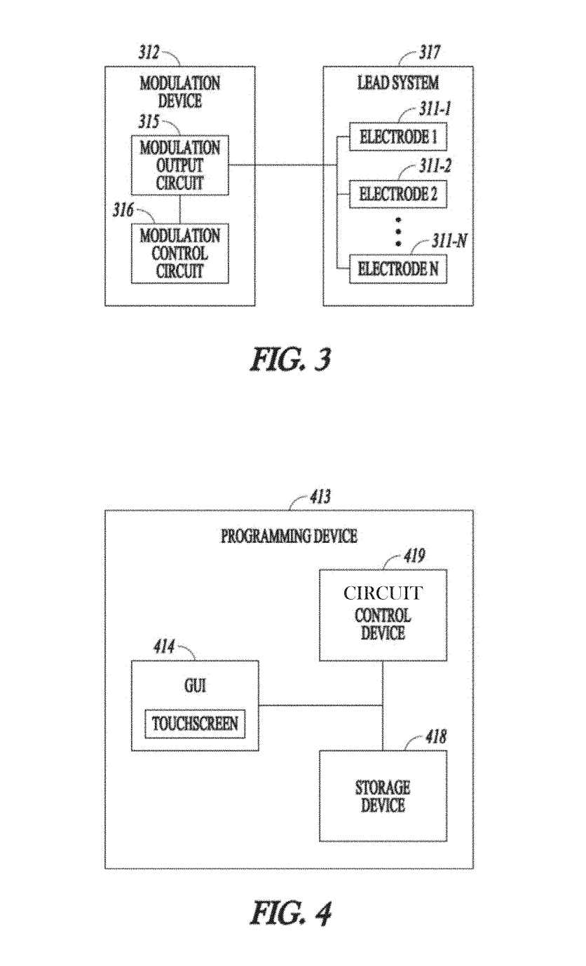

FIG. 2 illustrates an embodiment of a neuromodulation system. The illustrated system 210 includes electrodes 211, a modulation device 212, and a programming device 213. The electrodes 211 are configured to be placed on or near one or more neural targets in a patient. The modulation device 212 is configured to be electrically connected to electrodes 211 and deliver neuromodulation energy, such as in the form of electrical pulses, to the one or more neural targets though electrodes 211. The delivery of the neuromodulation is controlled by using a plurality of modulation parameters, such as modulation parameters specifying the electrical pulses and a selection of electrodes through which each of the electrical pulses is delivered. In various embodiments, at least some parameters of the plurality of modulation parameters are programmable by a user, such as a physician or other caregiver. The programming device 213 provides the user with accessibility to the user-programmable parameters. In various embodiments, the programming device 213 is configured to be communicatively coupled to modulation device via a wired or wireless link. In various embodiments, the programming device 213 includes a graphical user interface (GUI) 214 that allows the user to set and/or adjust values of the user-programmable modulation parameters.

FIG. 3 illustrates an embodiment of a modulation device 312, such as may be implemented in the neuromodulation system 210 of FIG. 2. The illustrated embodiment of the modulation device 312 includes a modulation output circuit 315 and a modulation control circuit 316. Those of ordinary skill in the art will understand that the neuromodulation system 210 may include additional components such as sensing circuitry for patient monitoring and/or feedback control of the therapy, telemetry circuitry and power. The modulation output circuit 315 produces and delivers neuromodulation pulses. The modulation control circuit 316 controls the delivery of the neuromodulation pulses using the plurality of modulation parameters. The lead system 317 includes one or more leads each configured to be electrically connected to modulation device 312 and a plurality of electrodes 311-1 to 311-N distributed in an electrode arrangement using the one or more leads. Each lead may have an electrode array consisting of two or more electrodes, which also may be referred to as contacts. Multiple leads may provide multiple electrode arrays to provide the electrode arrangement. Each electrode is a single electrically conductive contact providing for an electrical interface between modulation output circuit 315 and tissue of the patient, where N≧2. The neuromodulation pulses are each delivered from the modulation output circuit 315 through a set of electrodes selected from the electrodes 311-1 to 311-N. The number of leads and the number of electrodes on each lead may depend on, for example, the distribution of target(s) of the neuromodulation and the need for controlling the distribution of electric field at each target. In one embodiment, by way of example and not limitation, the lead system includes two leads each having eight electrodes.

The neuromodulation system may be configured to modulate spinal target tissue or other neural tissue. The configuration of electrodes used to deliver electrical pulses to the targeted tissue constitutes an electrode configuration, with the electrodes capable of being selectively programmed to act as anodes (positive), cathodes (negative), or left off (zero). In other words, an electrode configuration represents the polarity being positive, negative, or zero. Other parameters that may be controlled or varied include the amplitude, pulse width, and rate (or frequency) of the electrical pulses. Each electrode configuration, along with the electrical pulse parameters, can be referred to as a “modulation parameter set.” Each set of modulation parameters, including fractionalized current distribution to the electrodes (as percentage cathodic current, percentage anodic current, or off), may be stored and combined into a modulation program that can then be used to modulate multiple regions within the patient.

The number of electrodes available combined with the ability to generate a variety of complex electrical pulses, presents a huge selection of available modulation parameter sets to the clinician or patient. For example, if the neuromodulation system to be programmed has sixteen electrodes, millions of modulation parameter sets may be available for programming into the neuromodulation system. Furthermore, for example SCS systems may have thirty-two electrodes which exponentially increases the number of modulation parameters sets available for programming. To facilitate such selection, the clinician generally programs the modulation parameters sets through a computerized programming system to allow the optimum modulation parameters to be determined based on patient feedback or other means and to subsequently program the desired modulation parameter sets. A closed-loop mechanism may be used to identify and test modulation parameter sets, receive patient or clinician feedback, and further revise the modulation parameter sets to attempt to optimize stimulation paradigms for pain relief. The patient or clinician feedback may be objective and/or subjective metrics reflecting pain, paresthesia coverage, or other aspects of patient satisfaction with the stimulation.

FIG. 4 illustrates an embodiment of a programming device 413, such as may be implemented as the programming device 213 in the neuromodulation system of FIG. 2. The programming device 413 includes a storage device 418, a programming control circuit 419, and a GUI 414. The programming control circuit 419 generates the plurality of modulation parameters that controls the delivery of the neuromodulation pulses according to the pattern of the neuromodulation pulses. In various embodiments, the GUI 414 includes any type of presentation device, such as interactive or non-interactive screens, and any type of user input devices that allow the user to program the modulation parameters, such as touchscreen, keyboard, keypad, touchpad, trackball, joystick, and mouse. The storage device 418 may store, among other things, modulation parameters to be programmed into the modulation device. The programming device 413 may transmit the plurality of modulation parameters to the modulation device. In some embodiments, the programming device 413 may transmit power to the modulation device (e.g., modulation device 312 of FIG. 3). The programming control circuit 419 may generate the plurality of modulation parameters. In various embodiments, the programming control circuit 419 may check values of the plurality of modulation parameters against safety rules to limit these values within constraints of the safety rules.

In various embodiments, circuits of neuromodulation, including its various embodiments discussed in this document, may be implemented using a combination of hardware, software, and firmware. For example, the circuit of GUI 414, modulation control circuit 316, and programming control circuit 419, including their various embodiments discussed in this document, may be implemented using an application-specific circuit constructed to perform one or more particular functions or a general-purpose circuit programmed to perform such function(s). Such a general-purpose circuit includes, but is not limited to, a microprocessor or a portion thereof, a microcontroller or a portion thereof, and a programmable logic circuit or a portion thereof.

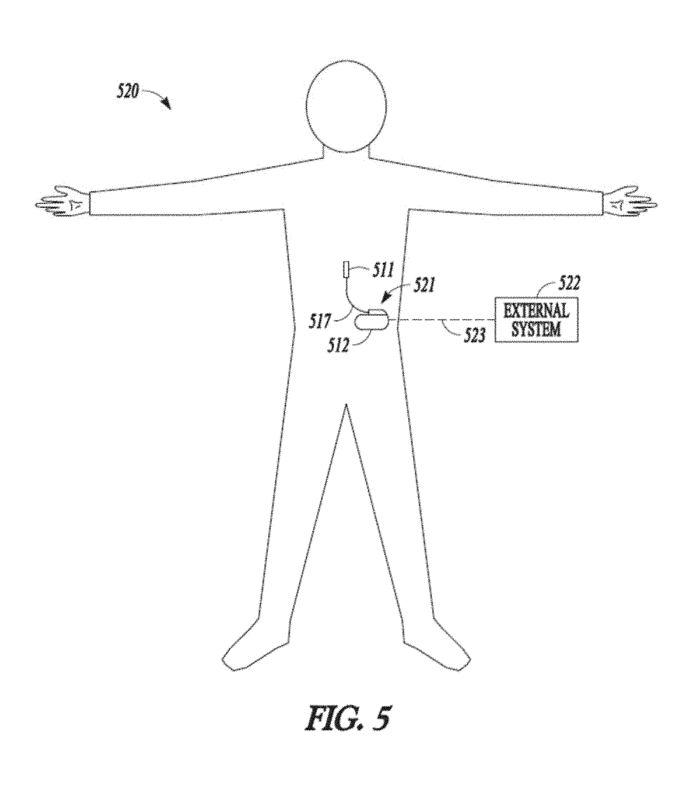

FIG. 5 illustrates, by way of example, an implantable neuromodulation system and portions of an environment in which system may be used. The system is illustrated for implantation near the spinal cord. However, neuromodulation system may be configured to modulate other neural targets. The system 520 includes an implantable system 521, an external system 522, and a telemetry link 523 providing for wireless communication between implantable system 521 and external system 522. The implantable system 521 is illustrated as being implanted in the patient's body. The implantable system 521 includes an implantable modulation device (also referred to as an implantable pulse generator, or IPG) 512, a lead system 517, and electrodes 511. The lead system 517 includes one or more leads each configured to be electrically connected to the modulation device 512 and a plurality of electrodes 511 distributed in the one or more leads. In various embodiments, the external system 402 includes one or more external (non-implantable) scanners each allowing a user (e.g. a clinician or other caregiver and/or the patient) to communicate with the implantable system 521. In some embodiments, the external system 522 includes a programming device intended for a clinician or other caregiver to initialize and adjust settings for the implantable system 521 and a remote control device intended for use by the patient. For example, the remote control device may allow the patient to turn a therapy on and off and/or adjust certain patient-programmable parameters of the plurality of modulation parameters. The remote control device may also provide a mechanism for the patient to provide feedback on the operation of the implantable neuromodulation system. Feedback may be metrics reflecting perceived pain, effectiveness of therapies, or other aspects of patient comfort or condition.

The neuromodulation lead(s) of the lead system 517 may be placed adjacent, e.g., resting near, or upon the dura, adjacent to the spinal cord area to be stimulated. For example, the neuromodulation lead(s) may be implanted along a longitudinal axis of the spinal cord of the patient. Due to the lack of space near the location where the neuromodulation lead(s) exit the spinal column, the implantable modulation device 512 may be implanted in a surgically-made pocket either in the abdomen or above the buttocks, or may be implanted in other locations of the patient's body. The lead extension(s) may be used to facilitate the implantation of the implantable modulation device 512 away from the exit point of the neuromodulation lead(s).

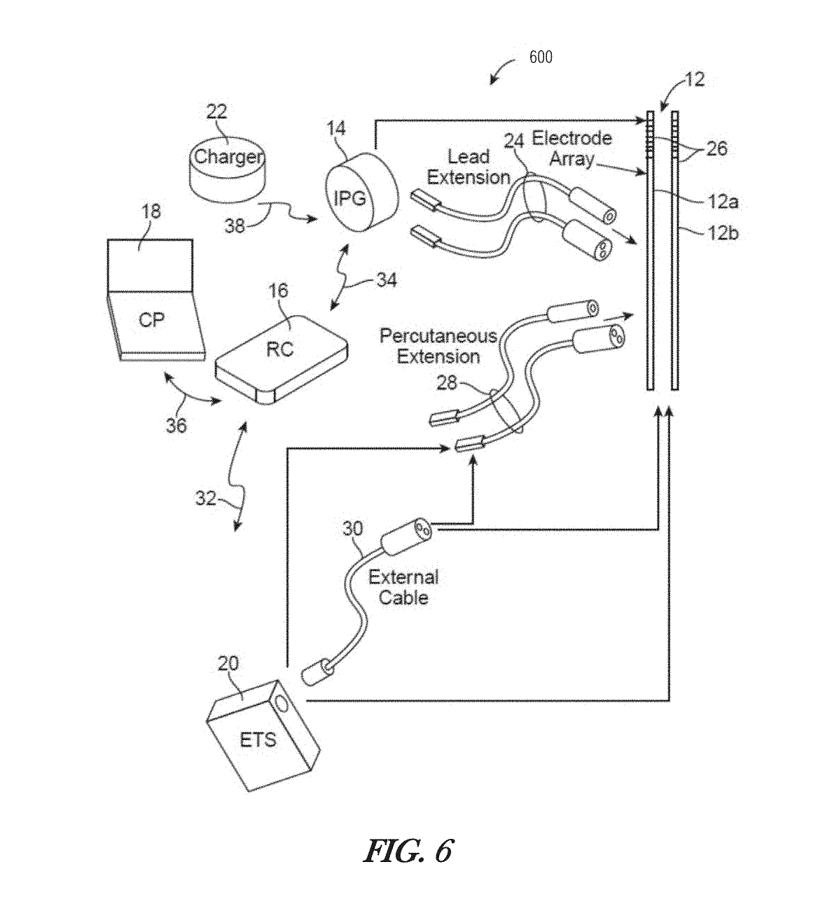

FIG. 6 illustrates, by way of example, an embodiment of an SCS system 600. The SCS system 600 generally comprises a plurality of neurostimulation leads 12 (in this case, two percutaneous leads 12a and 12b), an implantable: pulse generator (IPG) 14, an external remote control (RC) 16, a Clinician's Programmer (CP) 18, an External Trial Stimulator (ETS) 20, and an external charger 22.

The IPG 14 is physically connected via two lead extensions 24 to the neurostimulation leads 12, which carry a plurality of electrodes 26 arranged in an array. In the illustrated embodiment, the neurostimulation leads 12 are percutaneous leads, and to this end, the electrodes 26 are arranged in-line along the neurostimulation leads 12. The number of neurostimulation leads 12 illustrated is two, although any suitable number of neurostimulation leads 12 can be provided, including only one. Alternatively, a surgical paddle lead can be used in place of one or more of the percutaneous leads. As will also be described in further detail below, the IPG 14 includes pulse generation circuitry that delivers electrical stimulation energy in the form of a pulsed electrical waveform (i.e., a temporal series of electrical pulses) to the electrode array 26 in accordance with a set of stimulation parameters. The IPG 14 and neurostimulation leads 12 can be provided as an implantable neurostimulation kit, along with, e.g., a hollow needle, a stylet, a tunneling tool, and a tunneling straw.

The ETS 20 may also be physically connected via percutaneous lead extensions 28 or external cable 30 to the neurostimulation lead 12. The ETS 20, which has similar pulse generation circuitry as the IPG 14, also delivers electrical stimulation energy in the form of a pulsed electrical waveform to the electrode array 26 in accordance with a set of stimulation parameters. The major difference between the ETS 20 and the IPG 14 is that the ETS 20 is a non-implantable device that is used on a trial basis after the neurostimulation lead 12 has been implanted and prior to implantation of the IPG 14, to test the responsiveness of the stimulation that is to be provided. Thus, any functions described herein with respect to the IPG 14 can likewise be performed with respect to the ETS 20.

The RC 16 may be used to telemetrically control the ETS 20 via a bi-directional RF communications link 32. Once the IPG 14 and stimulation leads 12 are implanted, the RC 16 may be used to telemetrically control the IPG 14 via a bi-directional RF communications link 34. Such control allows the IPG 14 to be turned on or off and to be programmed with different stimulation programs after implantation. Once the IPG 14 has been programmed, and its power source has been charged or otherwise replenished, the IPG 14 may function as programmed without the RC 16 being present.

The CP 18 provides the user detailed stimulation parameters for programming the IPG 14 and ETS 20 in the operating room and in follow-up sessions. The CP 18 may perform this function by indirectly communicating with the IPG 14 or ETS 20, through the RC 16, via an IR communications link 36. Alternatively, the CP 18 may directly communicate with the IPG 14 or ETS 20 via an RF communications link (not shown).

The external charger 22 is a portable device used to transcutaneously charge the IPG 14 via an inductive link 38. Once the IPG 14 has been programmed, and its power source has been charged by the external charger 22 or otherwise replenished, the IPG 14 may function as programmed without the RC 16 or CP 18 being present.

For the purposes of this specification, the terms “neurostimulator,” “stimulator,” “neurostimulation,” and “stimulation” generally refer to the delivery of electrical energy that affects the neuronal activity of neural tissue, which may be excitatory or inhibitory; for example by initiating an action potential, inhibiting or blocking the propagation of action potentials, affecting changes in neurotransmitter/neuromodulator release or uptake, and inducing changes in neuro-plasticity or neurogenesis of tissue. For purposes of brevity, the details of the RC 16, ETS 20, and external charger 22 will not be described herein.

### Managing Magnetic Resonance Conditional Implants

Magnetic resonance imaging (MRI) subjects a person to large amounts of radio frequencies, which may affect implanted devices. The magnetic fields induced in an MRI may physically displace implants, induce radio frequency (RF) heating, or create image artifacts. The static magnetic field of an MRI may induce displacement forces and torques on ferromagnetic materials. Additionally, RF heating may be caused by currents induced by RF excitation pulses applied during MR scanning. As such, when a patient desires to search for an MRI scanning facility, there is a need to selectively filter the scanning facilities available in a geographic region to eliminate those facilities that have MRI scanners which are not safe for the patient based on the labeling restrictions of the implanted neurostimulator device.

The present disclosure describes several workflows, systems, methods, and devices to provide patients, physicians, clinicians, and technicians improvements to ensure MR Conditional implants are safe for a particular MRI scanning station, and provide better patient support. For example, patients are provided interactive tools that allow them to search for and identify safe MRI scanning facilities. Physicians, clinicians, and technicians are able to review MRI labels and ensure that the patient's implants are safe and compatible with the MRI scanner being used or planned on being used.

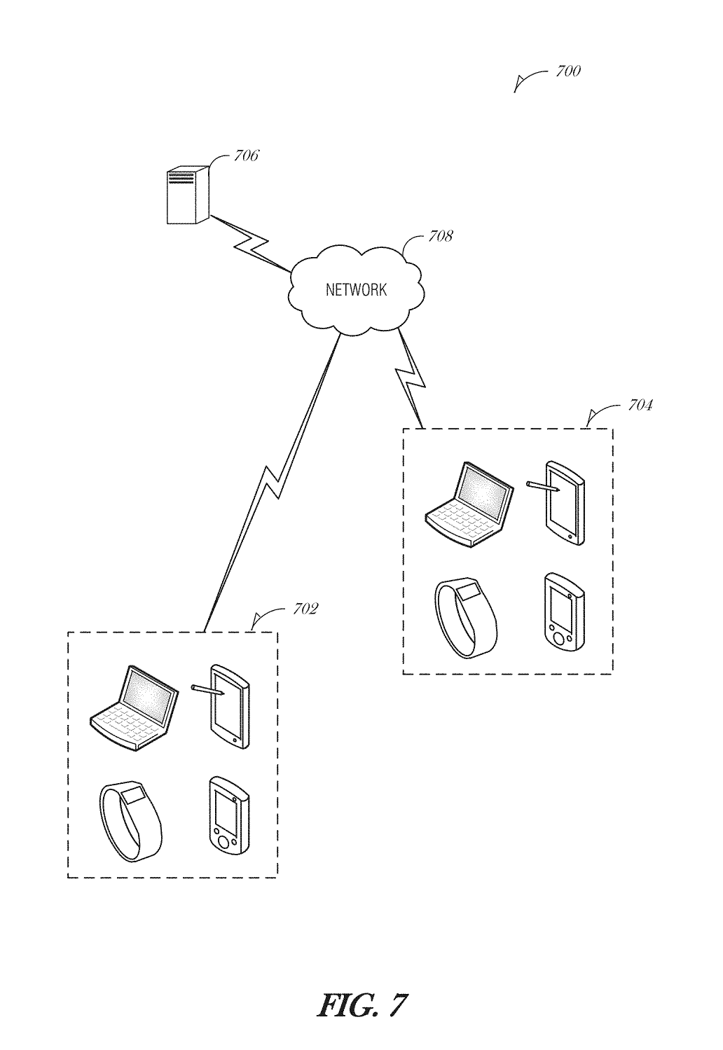

FIG. 7 illustrates, by way of example, an embodiment of an operational environment 700. The environment 700 includes a user device 702, a clinician device 704, and a server 706, all connected over a network 708. The user device 702 and clinician device 704 may be any type of computing device including, but not limited to a tablet, a desktop computer, a hybrid computer, a laptop, a wearable device (e.g., smartglasses or a smartwatch), a smartphone, a personal digital assistant (PDA), a handheld personal computer, or the like. The server 706 may be one or more computers acting in concert (e.g., in a server farm or a cloud environment) that provide a virtualized server environment. The server 706 may be a conventional server system that provides a service that listens on one or more active ports and processes requests received at such ports. The server 706 may act in response to specific apps on the user device 702 or clinician device 704. The communication to the server 706 from the user device 702 or clinician device 704 may be encrypted or otherwise secured using one or more security mechanisms, such as a public key infrastructure (PKI) scheme (e.g., Diffie-Hellman key exchange, RSA algorithms, etc.) or a symmetric key exchange (e.g., Data Encryption Standard (DES), Advanced. Encryption Standard (AES), etc.).

The network 708 may include local-area networks (LAN), wide-area networks (WAN), wireless networks (e.g., 802.11 or cellular network), the Public Switched Telephone Network (PSTN) network, ad hoc networks, personal area networks (e.g., Bluetooth) or other combinations or permutations of network protocols and network types. The network 708 may include a single local area network (LAN) or wide-area network (WAN), or combinations of LAN's or WAN's, such as the Internet. The various devices coupled to the network 708 may be coupled to the network 708 via one or more wired or wireless connections.

Applications (or apps) have become a mainstream commodity. Apps are provided to various computing platforms including tablets, desktops, smartphones, and the like. Apps may be provided to certain operating systems, such as Apple® or Android™, or may be generally available for all popular operating systems. An application may be made available to a user from an online repository (e.g., application store). The online repository may provide applications that have been reviewed and screened by the repository.

The patient may install an app on the user device 702 in order to interface with an implant or with the server 706 in order to obtain information about an implant. Although some example embodiments described herein refer to a single implant, it is understood that the patient may have multiple implants. The clinician device 704 may install a similar or same app and may be used by several different types of people including, but not limited to a physician, a clinician, a specialist, a technician, or the like. The clinician device 704 may be used to obtain similar information, such as MRI safety information, about one or several implants in the patient.

Implants, which include vascular implants (e.g., stents, clips, coils, valves, etc.), orthopedic implants (e.g., nails, wires, fixation systems, prostheses, etc.), active implants (e.g., pacemakers, neurostimulators, infusion pumps, etc.), surgical instruments (e.g., scissors, guidewires, manipulators, etc. and medical devices (e.g., pulse oximeters, anesthesia and monitoring equipment, injectors, ventilators, robotic systems, etc.) may be subject to an MR environment. Implants may be classified as being MR Safe, MR Conditional, or MR Unsafe using Food and Drug Administration (FDA) guidelines. Analogous regulatory bodies in other countries provide similar guidelines. An MR Safe implant is one that is not electrically conductive or magnetic. As such, an MR Safe implant will not be subject to magnetically induced forces or RF-induced heating. An example of an MR Safe implant is a polymer screw. Conversely, an MR Unsafe implant is one that is not safe in any MR environment. MR Conditional implants are those that are not likely to be displaced with a low enough magnetic field strength or will only heat a certain amount due to RF-induced heating.

MR safety information is typically provided in a MRI label. The MRI label includes certain information, such as the conditions of any clinical testing or non-clinical testing where the implant was found to be scanned safely. As per FDA recommendations (or other regulatory body recommendations), the MRI label should include the upper boundaries of the static field strength (measured in tesla (T)), maximum spatial field gradient (measured in gauss/cm or T/m), maximum MR system reported whole body averaged specific absorption rate (SAR), and additional instructions or information for sate use in the MR environment, such as positioning or restrictions on coil type.

In operation, the patient may use the user device 702 to search for and display MRI scanning locations based on various search criteria. The patient may obtain one or more operational aspects of one or more implants, which may be presently implanted or which the patient may foresee future implantation. The operational aspects may include various MRI safety information, as described above. The operational aspects may also include a type, model, manufacturer, version, or the like that describes the structure, function, use, or other aspect of the implant.

The user device 702 may access the implant directly, such as with a wireless RF connection, to query the implant and obtain operational aspects of the implant. Alternatively the user device 702 may query a networked source, such as the server 706 or another repository, to obtain information about the implant. The server 706 may house a patient database with electronic medical records, which may include the patient's medical history and implantation details. Optionally, the server 706 may access another system, such as a central electronic medical records database, in order to obtain information about the implant.

As another example, the user device 702 may be configured with details about the implant (or implants) that the patient has, by a physician or clinician at or around the time of implantation. For example, after the implant procedure is complete, the physician may assist the patient to download an application onto the user device 702 and configure the user device 702 with specifics about the implant.

Using the information about the implant, the patient (or another user) may use the user device 702 to search for a suitable MRI scanning facility. For example, the implant may be rated to operate safely within a 1.5 T MRI. The app on the user device 702 may be configured to search for MRI scanning stations in a geographic region with 1.5 T MRI scanners. The results may then be displayed in various formats, such as a list format or on a graphical map. Additional information may be provided with the search results, such as the street address, navigational directions, distance from the patient, hours of operation, type of MRI equipment available, scheduling information, insurance information, and the like.

Once at the MRI scanning station of choice, a technician, clinician, nurse, or other personnel may use the same or similar app to crosscheck the implant information of the patient with their own information about the MRI facilities onsite. This may be performed by looking onto the user device 702 or by loading an app on a clinician device 704. For example, the user device 702 may present a user interface that includes one or more of a search interface, an implant information interface, and a body limitation interface. The implant information interface may be selected to display information about the implant, such as the type of implant, MRI scanner information, implantation date, implantation location, and the like. The body limitation interface may display a form of a human body with indications of where it is safe or unsafe to scan, based on the location, type, or limitations of the implant.

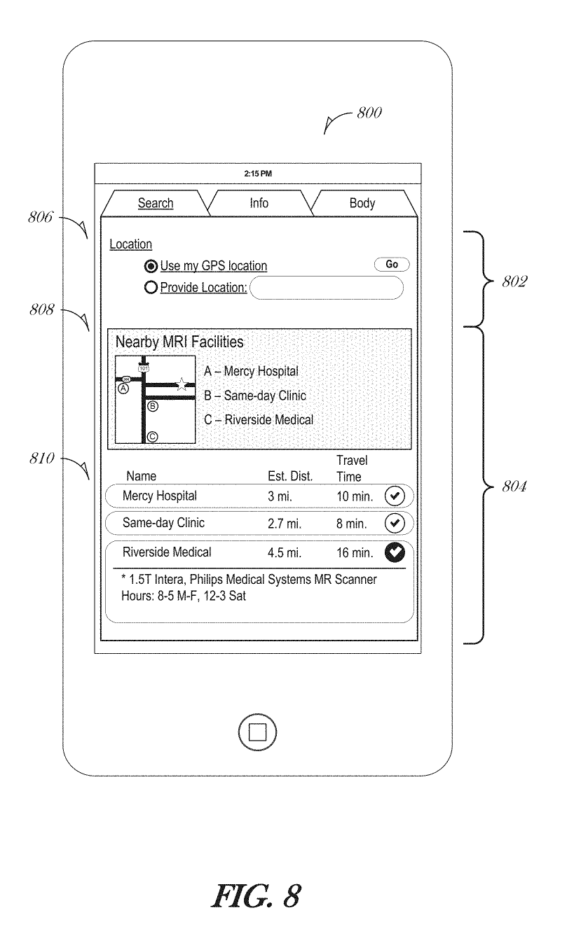

FIG. 8 illustrates, by way of example, an embodiment of a graphical user interface 800. The illustration of the particular graphical user interface 800 and the content included therein is provided as one non-limiting example; it is appreciated that numerous other configurations and designs may be implemented for such a graphical user interface.

The graphical user interface 800 includes a search interface 802 and a search results interface 804. The search interface 802 includes location controls 806. The user may provide a location or use the device's GPS location with the location controls 806. By default, in an example embodiment, the application will use the device's GPS location. The user may also provide a location, such as by typing in a c name or a geographic coordinate (e.g., latitude and longitude tuple).

In addition, although not illustrated in FIG. 8, if the user had multiple implants, a user interface control may be displayed to provide the user a mechanism to select which implant to filter on in the search results.

The search parameters may include the implant details (e.g., safety information, implant location, implant type, etc.), the user or device location, a search radius around the location (e.g., 10 miles, 50 km, 20 minutes travel, etc.), insurance information (e.g., preferred insurance providers), and the like. Using the search parameters, a database of MRI scanners and the corresponding facilities may be searched to identify compatible MRI scanners. The database of MRI scanners may be built by voluntary submissions by the clinics, hospitals, and other examination sites.

After a user has submitted a search, the search results are displayed in the search results interface 804. The search results interface 804 may include a mini-map 808 and zero or more listings 810. The mini-map 808 provides a navigational aid to the user and includes indicia of the listings 810, if any. The mini-map 808 may be an activateable control, for example, where the user may press or click on the mini-map 808 to zoom, pan, or otherwise manipulate the map view contained within. Alternatively, activating the mini-map 808 (e.g., by pressing or clicking on it) may navigate the user to another application, such as a map application or a navigational application, with the region of the mini-map 808 used to orient the map or navigational application to the corresponding region.

The listings 810 include details of the medical facilities that provide MRI scanners that are safe for the user, based on the implant details. The listings 810 may include the name, an estimated distance, and an estimated travel time. By selecting one of the listings 810, additional details may be displayed. In this example, the listing for “Riverside Medical” has been selected and a details of the location are displayed to the user.

If the device is incorporated into a navigation system, such as in a vehicle, the route information may be conveyed to the user with turn-by-turn directions. The route information may include a map. In addition, the route information or the map may indicate traffic conditions. In general, routing may take into consideration traffic levels, construction, weather, and other obstacles (e.g., games or events) that may impede or affect the user's progress. This is presented to the user in order to assist in decision making among several vendors.

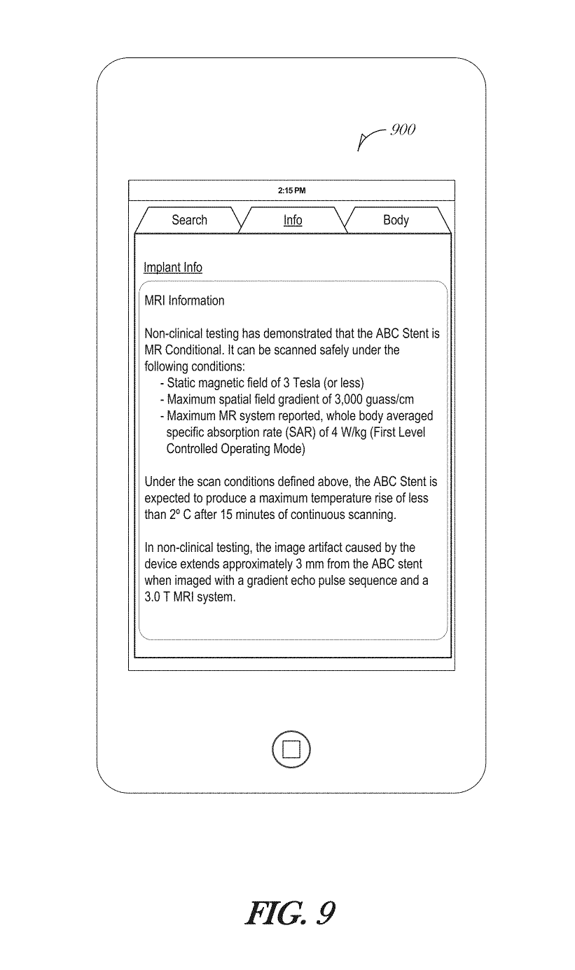

FIG. 9 illustrates, by way of example, an embodiment of a graphical user interface 900. The illustration of the particular graphical user interface 900 and the content included therein is provided as one non-limiting example; it is appreciated that numerous other configurations and designs may be implemented for such a graphical user interface. The graphical user interface 900 includes implant information, including an MRI label.

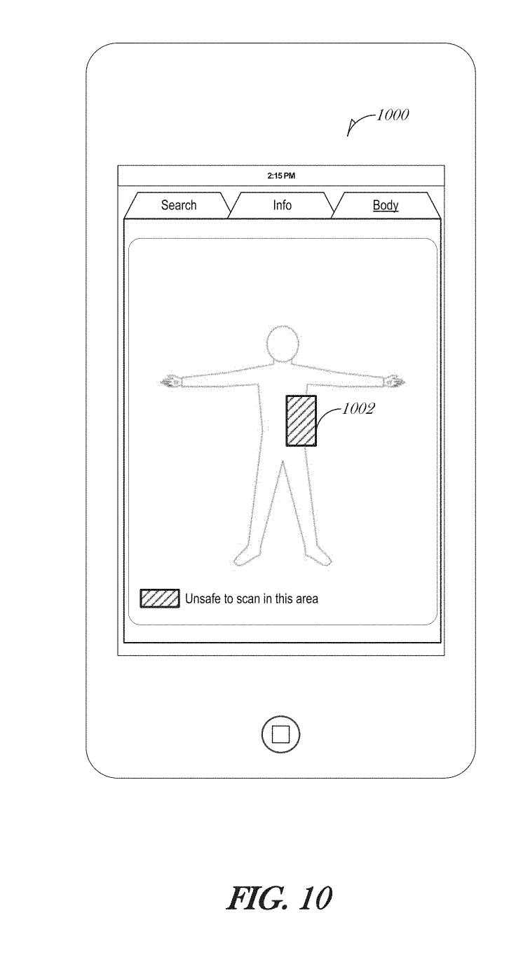

FIG. 10 illustrates, by way of example, an embodiment of a graphical user interface 1000. The illustration of the particular graphical user interface 1000 and the content included therein is provided as one non-limiting example; it is appreciated that numerous other configurations and designs may be implemented for such a graphical user interface. The graphical user interface 1000 includes a body limitation interface, which includes a form of a human body with indications 1002 of where it is unsafe to scan. It is understood that additional indications may be included on the body limitation interface, such as an affirmative indication of where it is safe to scan (the present interface illustrates safe areas by inference), for how long it is safe to scan, and the like.

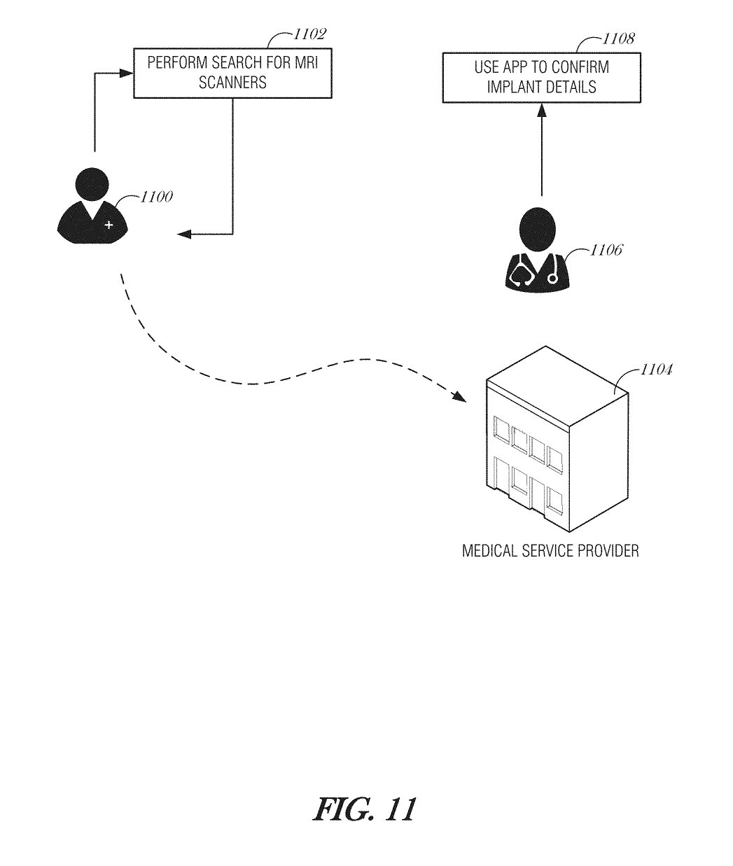

FIG. 11 illustrates, by way of example, an embodiment of data and control flow in a system. A user 1100 (e.g., patient) may install an app on a user device. The app may be installed by a physician or clinician, such as at an office visit or as part of an implantation procedure. The app may be configured to communicate with the implant. For example, the implant may be an implanted medical device (IMD) capable of short-range telemetry. Alternatively, some implants, such as stents or orthopedic prostheses may not be capable of communication. In such a case, the app may be configured with the details of the implant. The app may be pre-configured for those implants that are capable of communication as well.

The user 1100 may perform a search for MRI scanners (operation 1102). The search parameters may be provided from the user 1100 or be configured into the app, or a mix of these modalities. The search parameters may include at a minimum, the search location or region and parameters of the implanted device (or devices). The search location or region may be parameterized by a location and radius data pairing (e.g., the user's current location and a radius of 10 miles around the location), or a regional description (e.g., New York City). Other search location parameters may be used as well, such as to account for natural boundaries (e.g., rivers), traffic conditions, weather conditions, mass transit options (e.g., bus lines), etc.

The search may be performed at the user device operated by the user 1100 or may be performed remotely, such as at a server system. Search results are provided to the user 1100. Should the results be empty (e.g., no matches in the geographical search area with scanners that are compatible with the implants), then the user 1100 may adjust the search parameters and try searching again. The user 1100 may select a provider from the one of the results and schedule an appointment for a scan.

When the user 1100 visits the selected medical service provider 1104, a medical personnel 1106 (e.g., technician, clinician, nurse, etc.) may screen the user (e.g., crosscheck the user's implant data before allowing the user 1100 to be scanned). The medical personnel 1106 may request to user the user's device to access the app loaded thereon, in order to view the implant data associated with the user 1100 and confirm that the MRI scanning equipment at the medical service provider 1104 is compatible and safe for the user 1100. Optionally, the medical personnel 1106 may use an app that is similar to or the same as the app loaded on the user's device. The medical personnel 1106 may also user a body-view interface to confirm that the area to be scanned is a safe area to scan.

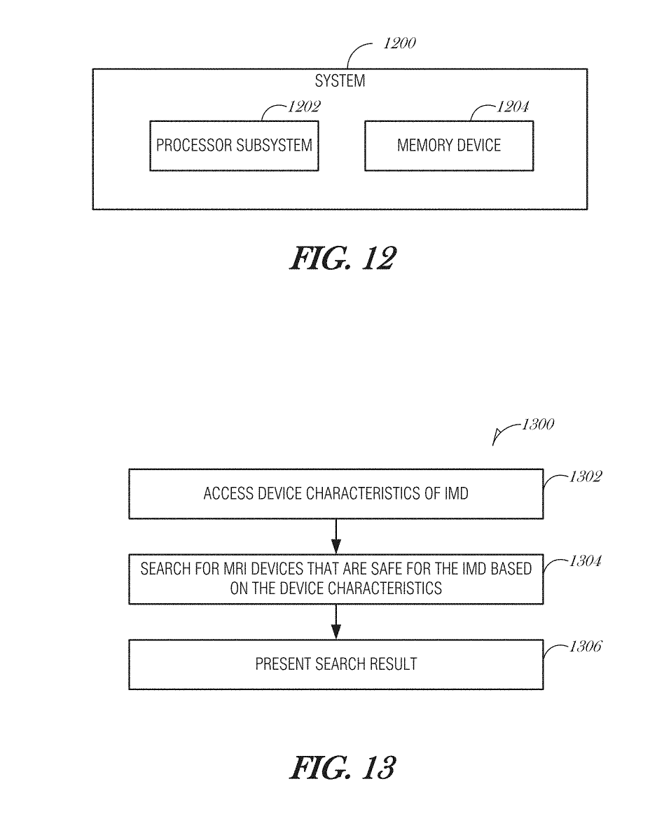

FIG. 12 illustrates, by way of example, an embodiment of a system 1200. The system 1200 may take on one of many forms. The system 1200 may be a mobile device (e.g., smartphone, laptop, tablet, etc.) or other computing device used by a patient or clinician, such as a user device 702.

The system 1200 includes a processor subsystem 1202 and a memory 1204. The processor subsystem 1202 may be any single processor or group of processors that act cooperatively. The memory 1204 may be any type of memory, including volatile or non-volatile memory. The memory 1204 may include instructions, which when executed by the processor subsystem 1202, cause the processor subsystem 1202 to access at an application executing on a user device, a set of device characteristics of an implantable medical device (IMD); search a database of magnetic resonance imaging (MRI) scanners to identify a search result, the search result including MRI scanners that are safe for the IMD based on the set of device characteristics, and the search result in a geographic area; and present the search result on the user device. Other user input may be used as search parameters, such as the insurance company network, hours of operation, attending physician, and the like.

In an embodiment, the set of device characteristics includes an MRI safety limitation of the IMD. In a further embodiment, the MRI safety limitation includes at least one of: a static magnetic field rating, a spatial gradient field rating, a maximum whole-body-averaged specific absorption rate (SAR) during normal operating mode, an upper value of a root mean square of a magnetic field, or a body scan location limitation. It is understood that other MRI safety limitations may be included and that this is not an exhaustive list. For example, the maximum gradient slew rate may be indicated on an MRI safety limitation.

The static magnetic field rating may also be referred to as “main field strength” and may be 1.5 T, 3 T, or higher, such as 7 T. The static magnetic field is a constant field that does not change over time. The strength of a static magnetic field flux density is expressed in tesla (T) or gauss (G).

The spatial gradient field rating may also be referred to as the “fringe field,” and refers to the static field gradient or magnetic force product. The spatial gradient field is measured in T/m or gauss/cm, where one tesla equals 10,000 gauss. Displacement forces are generally proportional to the spatial field gradient. MR vendors specify location and magnitude of the spatial field gradient in T/m or G/cm (which is 100 times the T/m values). Example values are 18 T/m or 1800 G/cm.

The SAR is measured in watts per kilogram (W/kg) and refers to the rate at which RF energy is deposited into tissue. The SAR is a function of the frequency, type, and number of RF pulses, the duration and repetition rate of the pulses, and the type of transmission coil. The SAR increases approximately as the square of the frequency. SAR limits are typically expressed as whole body, partial body, or local values. Examples of SAR limits include “whole body SAR limit of 2 W/kg for Normal Mode” and “for extremities up to 10 W/kg.”

An upper value of a root mean square of a magnetic field refers to the exposure limit. The root mean square (RMS) value of a time-varying function (e.g., B₁ and the imaging gradients) is derived by squaring the function and then determining the mean value of the squares obtained, and then taking the square root of that mean value. The Bₒ field in MRI technology refers to the static magnetic field (e.g., the main field). The B₁ field refers to the pulsed RF magnetic fields in the very high frequency domain. Where the Bₒ field is commonly produced by a solenoidal superconducting magnet, the B₁ field is produced by RF transmit coils operating in the near field, applied orthogonally to Bₒ. The B₁ field exposure limit is referred to as the B1_{RMS} value, and is related to the SAR value. Where the SAR value may be useful to indicate potential of tissue heating, a single SAR value may be insufficient to predict specific instances. Thus, the B1_{RMS} value is a more direct measure of the RF magnetic field and may be more suitable for predicting potential RF-induced heating.

The body scan location limitation refers to a region, portion, or area of a body that is sensitive to MR scanning. As such, MRI of the region, portion, or area indicated in the body scan location limitation should be avoided to ensure patient safety.

In an embodiment, the instructions to access the set of device characteristics comprise instructions to query the IMD and receive the set of device characteristics from the IMD. The IMD may be queried using a wireless or wired telemetry. The device characteristics may include various information, such as the IMD manufacturer, model, version, software version, etc., along with MRI safety information.

In an embodiment, the instructions to access the set of device characteristics comprise instructions to query a patient database and receive the set of device characteristics from the patient database. The patient database may be stored at a local or remote location with respect to the user device. The patient database may be maintained by a hospital system, a governmental agency, a private entity, or other organizations.

In an embodiment, the instructions to search the database of MRI scanners to identify the search result comprise instructions to receive a geographic search constraint at the user device and search the database of MRI scanners in the geographic area constrained by the geographic search constraint. The geographic search constraint may be a point and radius constraint, where the radius is expressed as a distance or a time of travel, and the location is expressed as a geographic coordinate, a street address, or some other indication of location. Thus, in an embodiment, the geographic search constraint includes a central locus and a search distance threshold. In a related embodiment, the central locus corresponds to a geolocation of the user device. The database of MRI scanners may be maintained by a private organization or collection of organizations, a public organization (e.g., a governmental agency), or a mixture of organizations of various types.

In an embodiment, the instructions to present the search result on the user device comprise instructions to present aspects of the MRI scanners in the search result. An example of aspects of the MRI scanners is provided in FIG. 8.

In an embodiment, the system 1200 includes instructions to obtain directions for use for the IMD for a specific MRI scanner of the MRI scanners in the search result and present the directions for use on the user device. Directions for use may include the MRI safety information, implant description, implant use, and other information about the implant or scanning constraints with respect to the implant.

In an embodiment, the system 1200 includes instructions to access a body scan location limitation from the set of device characteristics and present a graphical representation of a body with indications corresponding the body scan location limitation. A non-limiting example of a body view user interface is provided in FIG. 10.

In an embodiment, the system 1200 includes instructions to present the search result on a first user interface screen and present a device labeling on a second user interface screen. A non-limiting example of the device labeling (e.g., MRI labels) is provided in FIG. 9.

The user device may take on any form. In an embodiment, the user device comprises a smartphone.

FIG. 13 illustrates, by way of example, an embodiment of a method 1300. At 1302, a set of device characteristics of an implantable medical device (IMD) is accessed at an application executing on a user device. In an embodiment, the set of device characteristics includes an MRI safety limitation of the IMD. In a further embodiment, the MRI safety limitation includes at least one of: a static magnetic field rating, a spatial gradient field rating, a maximum whole-body-averaged specific absorption rate (SAR) during normal operating mode, an upper value of a root mean square of a magnetic field, or a body scan location limitation. It is understood that other MRI safety limitations may be included and that this is not an exhaustive list. For example, the maximum gradient slew rate may be indicated on an MRI safety limitation.

At 1304, a database of magnetic resonance imaging (MRI) scanners is searched to identify a search result, the search result including MRI scanners that are safe for the IMD based on the set of device characteristics, and the search result in a geographic area.

At 1306, the search result is presented on the user device.

In an embodiment, accessing the set of device characteristics comprises querying the IMD and receiving the set of device characteristics from the IMD.

In an embodiment, accessing the set of device characteristics comprise querying a patient database and receiving the set of device characteristics from the patient database.

In an embodiment, searching the database of MRI scanners to identify the search result comprises receiving a geographic search constraint at the user device and searching the database of MRI scanners in the geographic area constrained by the geographic search constraint.

In an embodiment, presenting the search result on the user device comprises presenting aspects of the MRI scanners in the search result.

A processor subsystem may be used to execute the instruction on the machine-readable medium. The processor subsystem may include one or more processors, each with one or more cores. Additionally, the processor subsystem may be disposed on one or more physical devices. The processor subsystem may include one or more specialized processors, such as a graphics processing unit (GPU), a digital signal processor (DSP), a field programmable gate array (FPGA), or a fixed function processor.

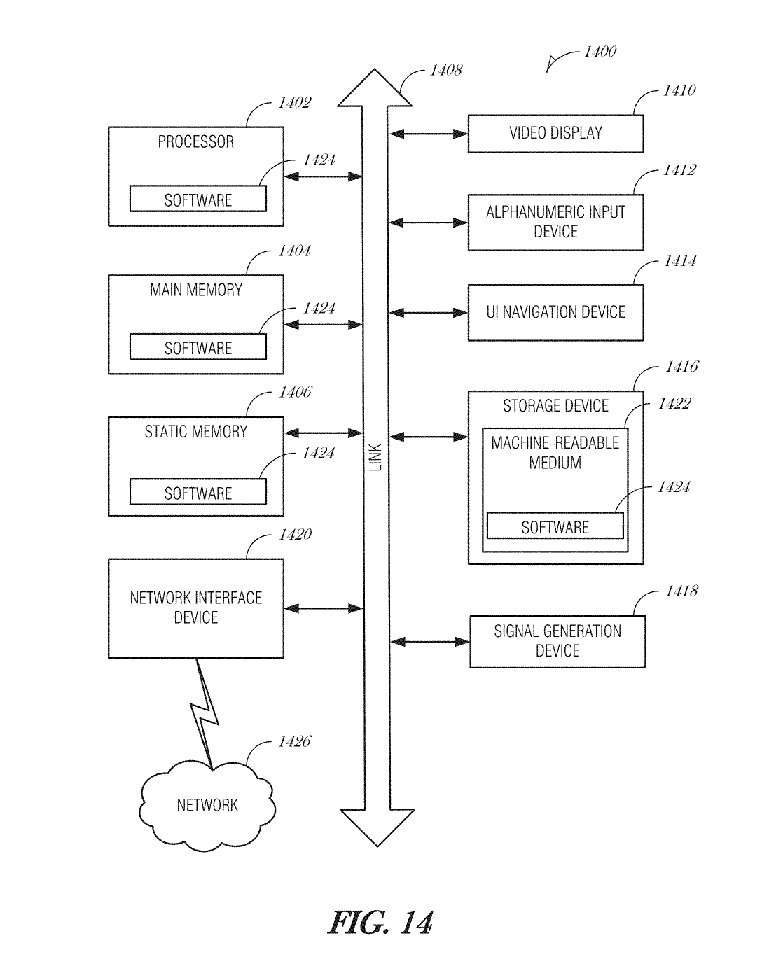

FIG. 14 is a block diagram illustrating a machine in the example form of a computer system 1400, within which a set or sequence of instructions may be executed to cause the machine to perform any one of the methodologies discussed herein, according to an example embodiment. In alternative embodiments, the machine operates as a standalone device or may be connected (e.g., networked) to other machines. In a networked deployment, the machine may operate in the capacity of either a server or a client machine in server-client network environments, or it may act as a peer machine in peer-to-peer (or distributed) network environments. The machine may a personal computer (PC), a tablet PC, a hybrid tablet, a personal digital assistant (PDA), a mobile telephone, an implantable pulse generator (IPG), an external remote control (RC), a Clinician's Programmer (CP), an External Trial Stimulator (ETS), or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein. Similarly, the term “processor-based system” shall be taken to include any set of one or more machines that are controlled by or operated by a processor (e.g., a computer) to individually or jointly execute instructions to perform any one or more of the methodologies discussed herein.

Example computer system 1400 includes at least one processor 1402 (e.g., a central processing unit (CPU), a graphics processing unit (GPU) or both, processor cores, compute nodes, etc.), a main memory 1404 and a static memory 1406, which communicate with each other via a link 1408 (e.g., bus). The computer system 1400 may further include a video display unit 1410, an alphanumeric input device 1412 (e.g., a keyboard), and a user interface (UI) navigation device 1414 (e.g., a mouse). In one embodiment, the video display unit 1410, input device 1412 and UI navigation device 1414 are incorporated into a touch screen display. The computer system 1400 may additionally include a storage device 1416 (e.g., a drive unit), a signal generation device 1418 (e.g., a speaker), a network interface device 1420, and one or more sensors (not shown), such as a global positioning system (GPS) sensor, compass, accelerometer, or other sensor.

The storage device 1416 includes a machine-readable medium 1422 on which is stored one or more sets of data structures and instructions 1424 (e.g., software) embodying or utilized by any one or more of the methodologies or functions described herein. The instructions 1424 may also reside, completely or at least partially, within the main memory 1404, static memory 1406, and/or within the processor 1402 during execution thereof by the computer system 1400, with the main memory 1404, static memory 1406, and the processor 1402 also constituting machine-readable media.

While the machine-readable medium 1422 is illustrated in an example embodiment to be a single medium, the term “machine-readable medium” may include a single medium or multiple media (e.g., a centralized or distributed database, and/or associated caches and servers) that store the one or more instructions 1424. The term “machine-readable medium” shall also be taken to include any tangible medium that is capable of storing, encoding or carrying instructions for execution by the machine and that cause the machine to perform any one or more of the methodologies of the present disclosure or that is capable of storing, encoding or carrying data structures utilized by or associated with such instructions. The term “machine-readable medium” shall accordingly be taken to include, but not be limited to, solid-state memories, and optical and magnetic media. Specific examples of machine-readable media include non-volatile memory, including but not limited to, by way of example, semiconductor memory devices (e.g., electrically programmable read-only memory (EPROM), electrically erasable programmable read-only memory (EEPROM)) and flash memory devices; magnetic disks such as internal hard disks and removable disks; magneto-optical disks; and CD-ROM and DVD-ROM disks.

The instructions 1424 may further be transmitted or received over a communications network 1426 using a transmission medium via the network interface device 1420 utilizing any one of a number of well-known transfer protocols (e.g., HTTP). Examples of communication networks include a local area network (LAN), a wide area network (WAN), the Internet, mobile telephone networks, plain old telephone (POTS) networks, and wireless data networks (e.g., Wi-Fi, 3G, and 4G LTE/LTE-A or WiMAX networks). The term “transmission medium” shall be taken to include any intangible medium that is capable of storing, encoding, or carrying instructions for execution by the machine, and includes digital or analog communications signals or other intangible medium to facilitate communication of such software.

The above detailed description is intended to be illustrative, and not restrictive. The scope of the disclosure should, therefore, be determined with references to the appended claims, along with the full scope of equivalents to which such claims are entitled.

What is claimed is:

1. A system comprising:
a processor subsystem; and
a memory device comprising instructions, which when executed by the processor subsystem, cause the processor subsystem to:
access at an application executing on a user device, a set of device characteristics of an implantable medical device (IMD);
search a database of magnetic resonance imaging (MRI) scanners to identify a search result, the search result including MRI scanners that are safe for the IMD based on the set of device characteristics, and the search result in a geographic area; and
present the search result on the user device.

2. The system of claim 1, wherein the set of device characteristics includes an MRI safety limitation of the IMD.

3. The system of claim 2, wherein the MRI safety limitation includes at least one of: a static magnetic field rating, a spatial gradient field rating, a maximum whole-body-averaged specific absorption rate (SAR) during normal operating mode, an upper value of a root mean square of a magnetic field, or a body scan location limitation.

4. The system of claim 1, wherein the instructions to access the set of device characteristics comprise instructions to:
query the IMD; and
receive the set of device characteristics from the IMD.

5. The system of claim 1, wherein the instructions to access the set of device characteristics comprise instructions to:
query a patient database; and
receive the set of device characteristics from the patient database.

6. The system of claim 1, wherein the instructions to search the database of MRI scanners to identify the search result comprise instructions to:
receive a geographic search constraint at the user device; and
search the database of Mill scanners in the geographic area constrained by the geographic search constraint.

7. The system of claim 6, wherein the geographic search constraint includes central locus and a search distance threshold.

8. The system of claim 6, wherein the central locus corresponds to a geolocation of the user device.

9. The system of claim 1, wherein the instructions to present the search result on the user device comprise instructions to:
present aspects of the MRI scanner in the search result.

10. The system of claim 1, further comprising instructions to:
obtain directions for use for the IMD for a specific MRI scanner of the MRI scanners in the search result; and
present the directions for use on the user device.

11. The system of claim 1, further comprising instructions to:
access a body scan location limitation from the set of device characteristics; and
present a graphical representation of a body with indications corresponding the body scan location limitation.

12. The system of claim 1, further comprising instructions to:
present the search result on a first user interface screen; and
present a device labeling on a second user interface screen.

13. A method comprising:
accessing at an application executing on a user device, a set of device characteristics of an implantable medical device (IMD);
searching a database of magnetic resonance imaging (MRI) scanners to identify a search result, the search result including MRI scanners that are safe for the IMD based on the set of device characteristics, and the search result in a geographic area; and
presenting the search result on the user device.

14. The method of claim 13, wherein the set of device characteristics includes an MRI safety limitation of the IMD.

15. The method of claim 14, wherein the MRI safety limitation includes at least one of: a static magnetic field rating, a spatial gradient field rating, a maximum whole-body-averaged specific absorption rate (SAR) during normal operating mode, an upper value of a root mean square of a magnetic field, or a body scan location limitation.

16. The method of claim 13, wherein accessing the set of device characteristics comprises:
querying the IMD; and
receiving the set of device characteristics from the IMD.

17. The method of claim 13, wherein accessing the set of device characteristics comprises:
querying a patient database; and
receiving the set of device characteristics from the patient database.

18. The method of claim 13, wherein searching the database of MRI scanners to identify the search result comprises:
receiving a geographic search constraint at the user device; and
searching the database of MRI scanners in the geographic area constrained by the geographic search constraint.

19. The method of claim 13, wherein presenting e search result on the user device comprises:
presenting aspects of the MRI scanners in the search result.

20. A non-transitory machine-readable medium including instructions, which when executed by a machine, cause the machine to:
access at an application executing on a user device, a set of device characteristics of an implantable medical device (IMD);
search a database of magnetic resonance imaging (MRI) scanners to identify a search result, the search result including MRI scanners that are safe for the IMD based on the set of device characteristics, and the search result in a geographic area; and
present the search result on the user device.
